(19) United States
(12) Patent Application Publication
(10) Pub. No.: US 2013/0288454 A1
(43) Pub. Date: Oct. 31, 2013

(54) METHOD FOR SEPARATING A PRODUCT SUBSTRATE FROM A CARRIER SUBSTRATE

(71) Applicant: Jürgen Burggraf, Scharding (AT)

(72) Inventor: Jürgen Burggraf, Scharding (AT)

(73) Assignee: EV Group E. Thallner GmbH

(21) Appl. No.: 13/978,159

(22) PCT Filed: Jan. 17, 2011
(86) PCT No.: PCT/EP2011/000173

§ 371 Date: Jul. 3, 2013

(51) Int. Cl. H01L 21/02

(52) U.S. Cl. CPC H01L 21/02016
USPC 438/460

(57) ABSTRACT

The invention relates to a method for stripping a product substrate from a carrier substrate which is connected to the product substrate by an interconnect layer with the following steps, especially the following sequence:
application of solvents to one flat side of the carrier substrate facing away from the interconnect layer,
flow of a throughflow portion of the solvent through the carrier substrate,
at least partial detachment of the interconnect layer, predominantly by the throughflow portion and
stripping of the product substrate from the carrier substrate.

### FIELD OF THE INVENTION

The invention relates to a method for stripping a product substrate from a carrier substrate.

### BACKGROUND OF THE INVENTION

The back-thinning of product substrates is often necessary in the semiconductor industry and can take place mechanically and/or chemically. For back-thinning purposes, product substrates are generally fixed temporarily onto a carrier. There are various methods for fixing. The carrier material may be, for example, films, glass substrates or silicon wafers.

Depending on the carrier materials used and the interconnect layer used between the carrier and the product substrate, various methods are known for dissolving or destroying the interconnect layer, such as for example the use of UV-light, laser beams, temperature action, or solvent.

Stripping increasingly constitutes one of the most critical process steps since the thin substrates, having substrate thicknesses of a few microns, break easily during stripping/removal or suffer damage due to the forces necessary for the process of stripping.

Moreover the thin substrates have little or no dimensional stability and are typically rolled up without support material. Therefore fixing and supporting of the wafers are essentially critical during handling of the back-thinned wafers.

Often the stripping, especially when using a solvent to dissolve the interconnect layer, is very time-consuming.

Therefore, it is an object of this invention to devise a device and a method in order to detach a product substrate from a carrier as nondestructively, promptly and simply as possible.

### SUMMARY OF THE INVENTION

This object is achieved with the features of Claim 1. Advantageous developments of the invention are given in the dependent claims. All combinations of at least two of the features given in the specification, the claims and/or the figures also fall within the framework of the invention. At the given value ranges, values within the indicated limits will also be disclosed as boundary values and will be claimed in any combination.

The present invention is based on the idea of dissolving the interconnect layer using a solvent, but not exclusively from the lateral peripheral edge of the interconnect layer. According to one aspect of the present invention, the interconnect layer is detached over an area as large as possible on the cement surface toward the carrier substrate, especially supported by cavitation generating means, preferably an ultrasonic transmitter in contact with the solvent. This is achieved as claimed in the invention in that a carrier substrate is penetrated (i.e., perforated) by channels, and/or a porous carrier substrate is used. The solvent thus acquires essentially blanket access to the interconnect layer and can attack and dissolve the interconnect layer essentially along the entire contact surface to the carrier substrate in a blanket manner.

As used herein, the term “product substrate” refers to a product substrate, for example a semiconductor wafer, which is conventionally thinned to a thickness between 0.5 μm and 250 μm, the tendency being to thinner and thinner product substrates.

Carriers are for example a carrier substrate with a thickness between 50 μm and 5000 μm, preferably between 500 μm and 1000 μm.

The interconnect layer can be a cement, for example a soluble cement, especially a thermoplastic, which is applied in a blanket manner, and the adhesive force in the center can be reduced by an adhesion-reducing layer, for example a fluoropolymer, preferably Teflon.

A chuck is especially suitable as a receiving means, especially a spinner chuck for accommodating the carrier substrate, especially by means of negative pressure, for example on suction paths, holes or suction cups. Alternatively mechanical accommodation, for example by lateral clamps, is contemplated. Accommodation takes place electrostatically in another alternative configuration.

Stripping means when using a film frame encompass the film mounted on the film frame and a film frame receiver which applies force and which accommodates the film frame. Otherwise the stripping means encompass a chuck which applies a tensile force to the carrier substrate, especially by means of vacuum paths provided on the chuck.

In one advantageous embodiment of the invention it is provided that the interconnect layer is detached uniformly along the carrier substrate. The more uniform the stripping of the interconnect layer is, especially by providing a plurality of channels or by permeation of a porous carrier part substrate, the carrier substrate can be stripped especially carefully from the product substrate.

According to another embodiment of the invention it is advantageously provided that there is a solvent reservoir for holding the solvent. The reservoir is preferably of variable volume and is formed by a film frame and a flexible film connected to the film frame, and the solvent is applied, especially by feeding the solvent. Here as claimed in the invention reference is made in full scope to the specification, the description of the figures, the claims and the drawings of European patent application EP 10 004 313.2 which accordingly should be considered as published at the same time.

If during throughflow of the flow portion and/or detachment of the interconnect layer, the solvent is exposed to ultrasonic vibrations, especially by exposure to an ultrasonic transmitter on the flat side of the carrier substrate, the method as claimed in the invention is drastically accelerated. The diffusion of molecules of the solvent through pores and/or channels of the carrier substrate is accelerated by ultrasound and the dissolution of the interconnect layer also takes place much more quickly when dissolution is excited by ultrasonic vibrations. The reason for this lies in so-called cavitation. Cavitation is defined as the formation and dissolution of hollow cavities in liquids by pressure fluctuations. These cavities implode and thus produce extremely strong surface damage on a solid bordered by the liquid. The interconnect layer is at least partially mechanically destroyed by cavitation. This effect is known in engineering, mainly in marine navigation by the wear of the propellers of a ship and is generally undesirable. This invention thus differs from US 2004/0188861 A1 by the fact that the induced sonic waves not only transport the molecules more efficiently through the channels, but in addition cavitation is responsible for damage, i.e., break-down, of the adhesive.

Ultrasonic vibrations with a frequency between 16 kHz and 1 GHz, preferably between 500 kHz and 1500 kHz, and more preferably 800 kHz and 1200 kHz, are especially advantageous.

In another advantageous embodiment the solvent reservoir is made trough-shaped, as a result of which stripping of the product substrate can be achieved with a minimum solvent consumption.

The method as claimed in the invention is further accelerated by stripping of the product substrate from the carrier substrate, also called debonding, as a result of the blanket dissolution of the interconnect layer by lifting the carrier substrate.

Other advantages, features and details of the invention will become apparent from the following description of preferred exemplary embodiments and using the drawings.

### BRIEF DESCRIPTION OF THE DRAWINGS

FIG. 1 shows a schematic side view of a compound substrate consisting of product substrate, carrier substrate and interconnect layer on a film frame according to a first version of the method and

FIG. 2 shows a schematic side view of a compound substrate consisting of product substrate, carrier substrate and interconnect layer on a film frame according to a second version of the method.

### DETAILED DESCRIPTION OF PREFERRED EMBODIMENTS

The same components and parts with the same function are identified with the same reference numbers.

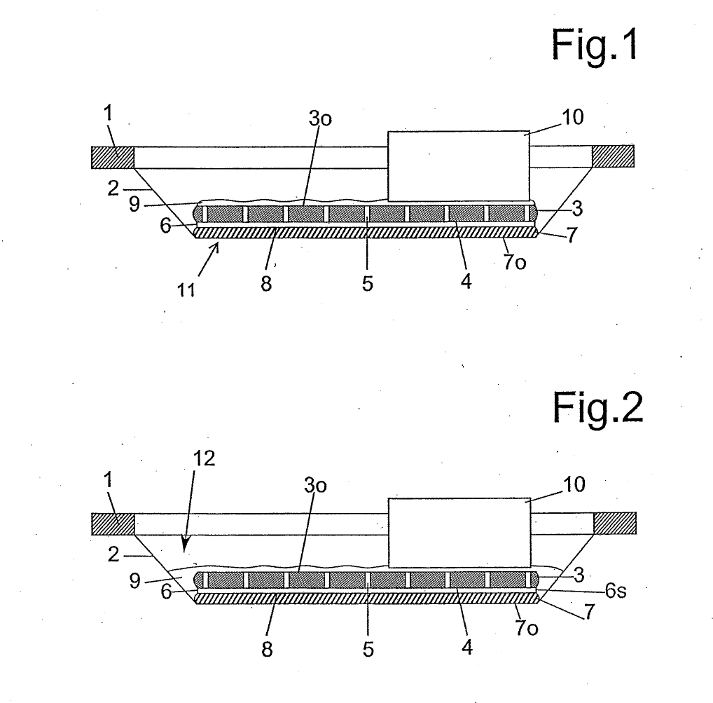

FIG. 1 shows a compound substrate 11 which is comprised of a carrier substrate 3, especially a wafer, a product substrate 7, especially a structure wafer, and an interconnect layer 6 which temporarily bonds the product substrate 7 on the carrier substrate 3, especially an adhesive.

The carrier substrate 3 as claimed in the invention is exposed to a solvent 9 for dissolving the interconnect layer 6 at least on one flat side 3o of the carrier substrate 3. Flat side 3o faces away from the interconnect layer 6 and is located at the top in the plane of the drawing. Thus the solvent 9 rests on the carrier substrate 3 (according to the embodiment as shown in FIG. 1) in a thin layer, without larger amounts running over the edge of the carrier substrate 3. Rather the solvent 9 in channels 5 and/or pores penetrate into the carrier substrate 3 due to the open porosity of the carrier substrate 3. Penetration of the solvent 9 takes place in this embodiment as a result of the force of gravity. The solvent 9 is applied by a means (not shown) for feeding of the solvent 9 or application of the solvent 9, for example a nozzle, which is connected to a solvent reservoir.

The compound substrate 11 rests on a film 2 of a film frame 1 which is provided as a flexible film. A concentric alignment of the compound substrate 11 to the annular film frame 1 is especially advantageous so that there is a uniform distance between the compound substrate 11 and the film frame 1. This distance and the flexibility of the film 2 are used by opposite application of force to the film frame 1 and to the compound substrate 11 in order to form a solvent reservoir 12 in which excess solvent 9 is collected. The solvent reservoir 12 thus has a trough shape.

To the extent—as shown in the embodiment according to FIG. 2—more solvent 9 is fed into the solvent reservoir 12, the compound substrate 11 is immersed completely into the solvent 9 so that the interconnect layer 6 is also detached from the solvent being in contact with the side periphery 6s of the interconnect layer 6.

Thus a “throughflow portion” of the solvent 9 flows through the carrier substrate 3 beginning from the flat side 3o to as far as the interconnect layer 6. As soon as the solvent 9 reaches the interconnect layer 6, the interconnect layer 6 begins to detach while the remaining portion of the solvent 9 remains on the carrier substrate 3.

An ultrasonic transmitter 10 is immersed in the remaining portion in order to expose the solvent 9 to ultrasonic vibrations. The ultrasonic vibrations are transmitted from the remaining portion through the carrier substrate via the throughflow portion of the solvent into the interconnect layer 6 so that both the permeation or the flow of the solvent 9 through the carrier substrate 3, and also the detachment of the interconnect layer, are greatly accelerated.

This invention is not limited to the use of a film frame 1 with film 2, but alternately it is conceivable as claimed in the invention to immerse the compound substrate 11 into a trough with solvent. The use of the film frame 1 is however advantageous since the film frame 1 can be used not only for preprocessing and further processing of the compound substrate 11 or of the product substrate 7, especially as a cutting frame, but can also be used at the same time as the solvent reservoir as claimed in the invention.

The channels 5 are preferably made as channels 5 which run especially transversely to the flat side 3o, preferably in a straight line, and which are distributed uniformly along the flat side 3o of the carrier substrate 3.

The product substrate 7 is stripped from the carrier substrate 3, after the at least partial detachment of the interconnect layer 6, by a tensile force being applied on the flat side 3o of the carrier substrate 3, i.e., to the top in the plane of the drawings, preferably with a receiving means for wafers, such as for example, a chuck. By applying a corresponding opposing force to the film frame 1 or to the product substrate 7, due to the flexibility of the film 2 careful stripping of the product substrate 7 from the carrier substrate 3 is achieved, beginning concentrically from the side edge of the compound substrate 11. The product substrate 7 on its flat side 7o, that faces away from the interconnect layer 6 is fixed on the film 2 which is made especially as an adhesive film. After stripping, only the product substrate 7 remains on the film 2 of the film frame 1 so that the product substrate 7 can be routed with the film frame 1 to further processing steps.

### REFERENCE NUMBER LIST

1 film frame
2 film
3 carrier substrate
3o flat side
5 channels
6 interconnect layer
6s side periphery
7 product substrate
7o flat side
9 solvent
10 ultrasonic transmitter
11 compound substrate
12 solvent reservoir

Having described the invention, the following is claimed:

1. Method for stripping a product substrate from a carrier substrate which is connected to the product substrate by an interconnect layer with the following steps, especially the following sequence:
application of solvents to one flat side of the carrier substrate facing away from the interconnect layer,
flow of a throughflow portion of the solvent through the carrier substrate,
at least partial detachment of the interconnect layer, especially predominantly by the throughflow portion and
stripping of the product substrate from the carrier substrate.
characterized in that
during throughflow of the throughflow portion and/or detachment of the interconnect layer, the solvent is exposed to ultrasonic vibrations by exposure to an ultrasonic transmitter on the flat side of the carrier substrate, wherein the ultrasonic vibrations have a frequency between 16 kHz and 1 GHz.

2. Method as claimed in claim 1, wherein throughflow takes place through channels of the carrier substrate.

3. Method as claimed in claim 1, wherein throughflow takes place by means of permeation through pores of the carrier substrate.

4. Method as claimed in claim 1, wherein the interconnect layer is dissolved uniformly distributed along the carrier substrate.

5. Method as claimed in claim 1, wherein there is a solvent reservoir for holding the solvent, a reservoir especially of variable volume, which is formed by a film frame and a flexible film connected to the film frame, and in which the solvent is applied, especially by feed of the solvent.

6. Method as claimed in claim 1, wherein said ultrasonic vibrations have a frequency between 500 kHz and 1500 kHz.

7. Method as claimed in claim 1, wherein said ultrasonic vibrations have a frequency between 800 kHz and 1200 kHz.

8. A method for removing a product substrate from a carrier substrate that is attached to the product substrate by an interconnect layer, said method comprised of the following steps:
applying a solvent to one flat side of a carrier substrate that is connected to a product substrate by an interconnect layer, said one flat side facing away from said interconnect layer and said carrier substrate having openings therethrough, wherein said one flat side is in communication with said interconnect layer through said openings, a throughflow portion of said solvent flowing through said opening in said carrier substrate to the interconnect layer;
exposing the throughflow portion of the solvent to ultrasonic vibrations having a frequency between 16 kHz and 1 GHz;
maintaining said ultrasonic vibrations until at least part of the interconnect layers detaches said product substrate from said carrier substrate; and
stripping said product substrate from said carrier substrate.
